(19) United States
(12) Patent Application Publication
(10) Pub. No.: US 2017/0229670 A1
(43) Pub. Date: Aug. 10, 2017

(54) COPPER (I) PYRAZOLATE DIMERS FOR ELECTROLUMINESCENT DEVICES

(71) Applicant: Dow Global Technologies LLC, Midland, MI (US)

(72) Inventors: David S. Laitar, Midland, MI (US); Thomas P. Clark, Midland, MI (US); Aaron A. Rachford, South Grafton, MA (US); Sukrit Mukhopadhyay, Midland, MI (US); Timothy S. De Vries, Midland, MI (US); David D. Devore, Midland, MI (US)

(73) Assignee: Dow Global Technologies LLC, Midland, MI (US)

(21) Appl. No.: 15/515,176

(22) PCT Filed: Oct. 6, 2015
(86) PCT No.: PCT/US2015/054112

§ 371 Date: Mar. 29, 2017

Related U.S. Application Data
(60) Provisional application No. 62/060,344, filed on Oct. 6, 2014.

(51) Int. Cl. H01L 51/50; C09K 11/06; C07F 9/655; C07F 9/6503; H01L 51/00; C07F 9/50

(52) U.S. Cl. CPC H01L 51/5016; H01L 51/009; H01L 51/0091; C07F 9/5045; C07F 9/65522; C07F 9/65033; C09K 11/06; C09K 2211/1007; C09K 2211/1044; C09K 2211/1088; C09K 2211/188

(57) ABSTRACT

The invention provides compositions comprising copper(I) pyrazolate dimer compounds for use in OLEDs applications. The inventive compositions can be used to generate visible light colors or a color blend in electronic devices.

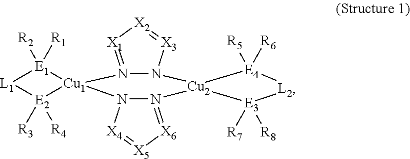

### REFERENCE TO RELATED APPLICATIONS

The present application claims the benefit of U.S. Provisional Application No. 62/060,344, filed on Oct. 6, 2014, incorporated herein by reference.

### BACKGROUND

Organic light emitting devices (OLEDs) are devices, in which the electroluminescent layer is a film containing at least one organic compound (emissive compound), which emits light in response to an electric current. Current emissive compounds, used in such electroluminescent devices, rely on iridium phosphorescent complexes, which potentially have high efficiency, due to harvesting of both triplet and singlet excitons, but are expensive to manufacture; or rely on fluorescent-based organic small molecules, which are typically less efficient, due to poor harvesting of triplet excitons. There is a need for new highly emissive, thermally stable compounds, which can harvest both singlet and triplet excitons, and which can be manufactured at reduced costs.

Some emissive metal-organic complexes are disclosed in the following references: US2007/0267959; US2007/0270592; US2013/0150581; WO2012056931A1; WO2012098263A1; US 20100044693(A1); 20110155954 A1; U.S. Pat. No. 8,053,090; JP4764047 (Abstract); JP2005101955A (Abstract); Dias et al. “Brightly Phosphorescent Trinuclear Copper(I) Complexes of Pyrazolates: Substituent Effects on the Supramolecular Structure and Photophysics” J. Am. Chem. Soc. 2005, 127, 7489; Omary et al. “Blue Phosphors of Dinuclear and Mononuclear Copper(I) and Silver(I) Complexes of 3,5-Bis(trifluoromethyl)pyrazolate and the Related Bis(pyrazolyl)borate” Inorg. Chem., 2003,42,8612; Igawa et al. “Highly efficient green organic light-emitting diodes containing luminescent tetrahedral copper(I) complexes” J. Mater. Chem. C, 2013, 1, 542. However, as discussed above, there remains a need for new compounds for emissive compounds that are highly emissive, thermally stable, and which can be manufactured at reduced costs. Such compounds should also enable long-lasting and highly efficient electronic devices. These needs have been met by the following invention.

### SUMMARY OF INVENTION

The invention provides a composition comprising a compound selected from Structure 1:

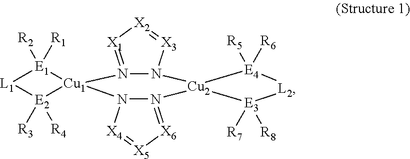

wherein E1, E2, E3 and E4 are each independently selected from the following: Nitrogen (N) or Phosphorus (P);

Cu1 and Cu2 are each Copper;

X1 is Nitrogen or C-R9, where C is Carbon, and R9 is selected from the following: hydrogen, a substituted or unsubstituted alkyl, a substituted or unsubstituted heteroalkyl, a substituted or unsubstituted aryl, or a substituted or unsubstituted heteroaryl;

X2 is Nitrogen or C-R10, where C is Carbon, and R10 is selected from the following: hydrogen, a substituted or unsubstituted alkyl, a substituted or unsubstituted heteroalkyl, a substituted or unsubstituted aryl, or a substituted or unsubstituted heteroaryl;

X3 is Nitrogen or C-R11, where C is Carbon, and R11 is selected from the following: hydrogen, a substituted or unsubstituted alkyl, a substituted or unsubstituted heteroalkyl, a substituted or unsubstituted aryl, or a substituted or unsubstituted heteroaryl;

X4 is Nitrogen or C-R12, where C is Carbon, and R12 is selected from the following: hydrogen, a substituted or unsubstituted alkyl, a substituted or unsubstituted heteroalkyl, a substituted or unsubstituted aryl, or a substituted or unsubstituted heteroaryl;

X5 is Nitrogen or C-R13, where C is Carbon, and R13 is selected from the following: hydrogen, a substituted or unsubstituted alkyl, a substituted or unsubstituted heteroalkyl, a substituted or unsubstituted aryl, or a substituted or unsubstituted heteroaryl; X6 is Nitrogen or C-R14, where C is carbon, and R14 is selected from the following: hydrogen, a substituted or unsubstituted alkyl, a substituted or unsubstituted heteroalkyl, a substituted or unsubstituted aryl, or a substituted or unsubstituted heteroaryl;

R1, R2, R3, R4, R5, R6, R7, R8 are each independently selected from the following: hydrogen, a substituted or unsubstituted alkyl, a substituted or unsubstituted heteroalkyl, a substituted or unsubstituted aryl, or a substituted or unsubstituted heteroaryl; and

wherein L1 and L2 are each independently selected from the following: a substituted or unsubstituted hydrocarbylene, or a substituted or unsubstituted heterohydrocarbylene;

and wherein, optionally, two or more R groups (R1 through R14) may form one or more ring structures;

and wherein, optionally, one or more hydrogens may be substituted with deuterium.

### BRIEF DESCRIPTION OF THE DRAWINGS

FIG. 1 depicts a solid state structure of an inventive Copper Complex 1.

FIG. 2 depicts the photoluminescence spectrum of [Cu(DPPB)(μ-pz)]₂ in a PMMA film at room temperature and 77K, to demonstrate the red-shift in the emission spectrum upon cooling to 77K.

### DETAILED DESCRIPTION OF THE INVENTION

A new class of copper(I) pyrazolate dimers have been discovered that are highly emissive and thermally stable. Emitters based on copper are cheaper to produce, and possess an electronic structure that will enable the construction of OLED devices that are as efficient as iridium-based emitters, but at substantially reduced costs. Here a novel class of sublimable emissive copper dimers has been discovered that contain neutral bidentate phosphines and pyrazolate-type anions. While not intending to be limiting, the red-shift in the temperature dependent emission spectra for these molecules, suggests that they can undergo a triplet harvesting through a thermally activated delayed fluorescence (TADF), to increase the quantum yield of emitted photons.

As discussed above, the invention provides a composition comprising a compound selected from Structure 1:

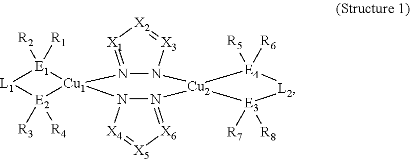

as described above.

An inventive composition may comprise a combination of two or more embodiments described herein.

An inventive compound of Structure 1 may comprise a combination of two or more embodiments described herein.

As used herein R1=R₁, R2=R₂, R3=R₃, and so forth. As used herein X1=X₁, E1=E₁, L1=L₁, and so forth.

In one embodiment, for Structure 1, X1 is Nitrogen or CR-9, where C is Carbon, and R9 is selected from the following: hydrogen, a substituted or unsubstituted alkyl, a substituted or unsubstituted aryl, or a substituted or unsubstituted heteroaryl;

X2 is Nitrogen or C-R10, where C is Carbon, and R10 is selected from the following: hydrogen, a substituted or unsubstituted alkyl, a substituted or unsubstituted aryl, or a substituted or unsubstituted heteroaryl;

X3 is Nitrogen or C-R11, where C is Carbon, and R11 is selected from the following: hydrogen, a substituted or unsubstituted alkyl, a substituted or unsubstituted aryl, or a substituted or unsubstituted heteroaryl;

X4 is Nitrogen or C-R12, where C is Carbon, and R12 is selected from the following: hydrogen, a substituted or unsubstituted alkyl, a substituted or unsubstituted aryl, or a substituted or unsubstituted heteroaryl;

X5 is Nitrogen or C-R13, where C is Carbon, and R13 is selected from the following: hydrogen, a substituted or unsubstituted alkyl, a substituted or unsubstituted aryl, or a substituted or unsubstituted heteroaryl;

X6 is Nitrogen or C-R14, where C is Carbon, and R14 is selected from the following: hydrogen, a substituted or unsubstituted alkyl, a substituted or unsubstituted aryl, or a substituted or unsubstituted heteroaryl;

R1, R2, R3, R4, R5, R6, R7, R8 are each independently selected from the following: hydrogen, a substituted or unsubstituted alkyl, a substituted or unsubstituted aryl, or a substituted or unsubstituted heteroaryl; and

wherein L1 and L2 are each independently selected from the following: a substituted or unsubstituted hydrocarbylene, or a substituted or unsubstituted heterohydrocarbylene;

and wherein, optionally, two or more R groups (R1 through R14) may form one or more ring structures;

and wherein, optionally, one or more hydrogens may be substituted with deuterium.

In one embodiment, for Structure 1, X1 is nitrogen or CR9, where C is Carbon, and R9 is selected from hydrogen, a substituted or unsubstituted alkyl, or a substituted or unsubstituted aryl.

In one embodiment, for Structure 1, X2 is nitrogen or C-R10, where C is carbon, and

R10 is selected from hydrogen, a substituted or unsubstituted alkyl, or a substituted or unsubstituted aryl.

In one embodiment, for Structure 1, X3 is nitrogen or C-R11, where C is Carbon, and R11 is selected from hydrogen, a substituted or unsubstituted alkyl, or a substituted or unsubstituted aryl.

In one embodiment, for Structure 1, X4 is nitrogen or C-R12, where C is Carbon, and R12 is selected from hydrogen, a substituted or unsubstituted alkyl, or a substituted or unsubstituted aryl.

In one embodiment, for Structure 1, X5 is nitrogen or C-R13, where C is Carbon, and R13 is selected from hydrogen, a substituted or unsubstituted alkyl, or a substitute or unsubstituted aryl.

In one embodiment, for Structure 1, X6 is nitrogen or C-R14, where C is carbon, and R14 is selected from hydrogen, a substituted or unsubstituted alkyl, or a substituted or unsubstituted aryl.

In one embodiment, for Structure 1, R1, R2, R3, R4, R5, R6, R7, R8 are each independently selected from the following: a substituted or unsubstituted aryl, or a substituted or unsubstituted heteroaryl.

In one embodiment, for Structure 1, L1 and L2 are each independently selected from the following: a substituted or unsubstituted arylene, or a substituted or unsubstituted heteroarylene.

In one embodiment, for Structure 1, two or more R groups (R1 through R14) do not form one or more ring structures.

In one embodiment, for Structure 1, one or more hydrogens are not substituted with deuterium.

In one embodiment, for Structure 1, E1, E2, E3 and E4 are each P.

In one embodiment, for Structure 1, R1, R2, R3, R4, R5, R6, R7 and R8 are each, independently, a substituted or unsubstituted aryl, further an unsubstituted aryl, and further each is phenyl.

In one embodiment, for Structure 1, at least two of X1, X2 and X3 are C—H; and at least two of X4, X5 and X6 are C—H.

In one embodiment, for Structure 1, X1 and X3 are each C—H; and X4 and X6 are each C—H.

In one embodiment, for Structure 1, L1 and L2 each, independently, comprise from 2 to 50 carbon atoms, further from 2 to 40 carbon atoms, further from 2 to 30 carbon atoms.

In one embodiment, for Structure 1, L1 and L2 are each, independently, a substituted or unsubstituted alkylene, a substituted or unsubstituted arylene, or a substituted or unsubstituted heteroarylene.

In one embodiment, for Structure 1, L1=L2.

In one embodiment, for Structure 1, L1 and L2 are each, independently, selected from the following structures a) through e):

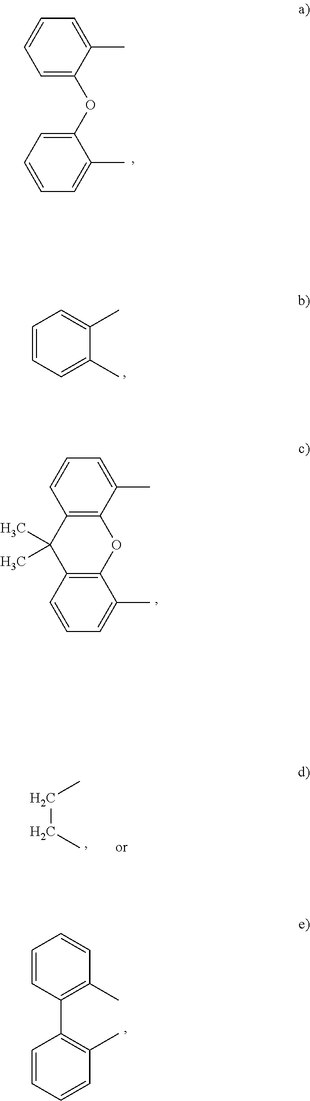

wherein, for each structure a) through e), the two “—” designations represent the respective bonds to E1 and E2, or the respective bonds to E3 and E4

In one embodiment, for Structure 1, L1 and L2 each, independently, comprise at least one phenylene group.

In one embodiment, the compound of Structure 1 is selected from the following structures 1) through 11):

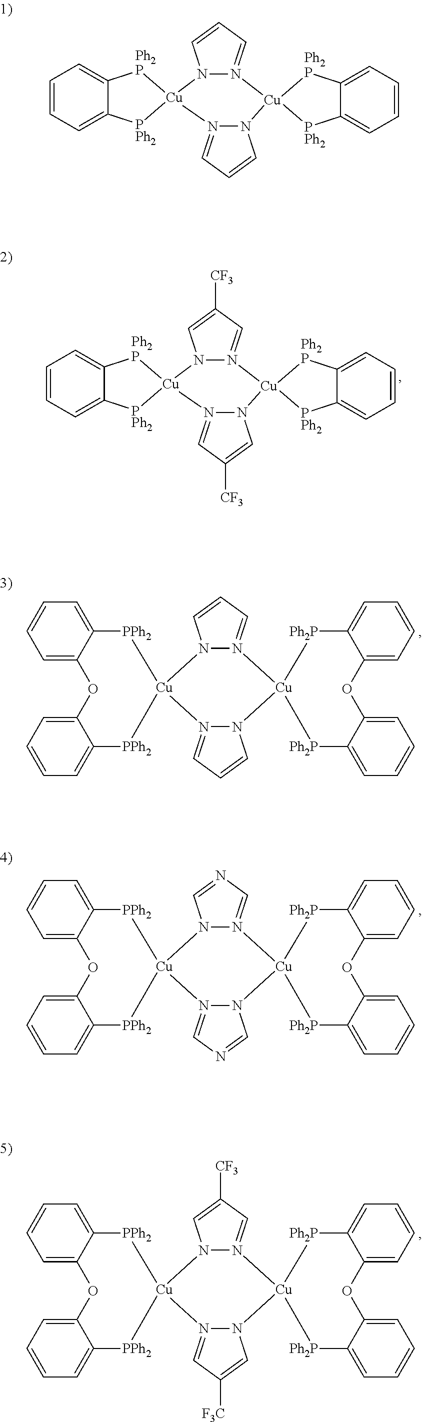

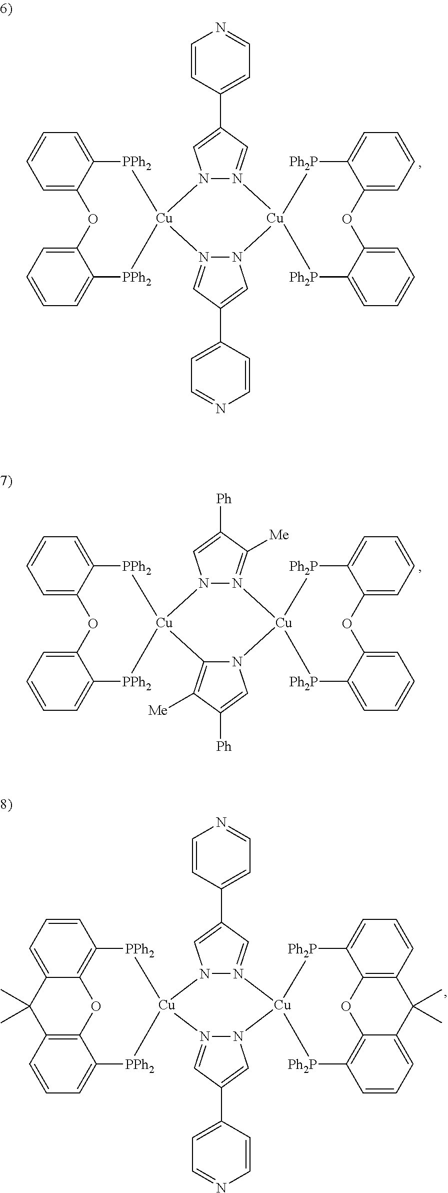

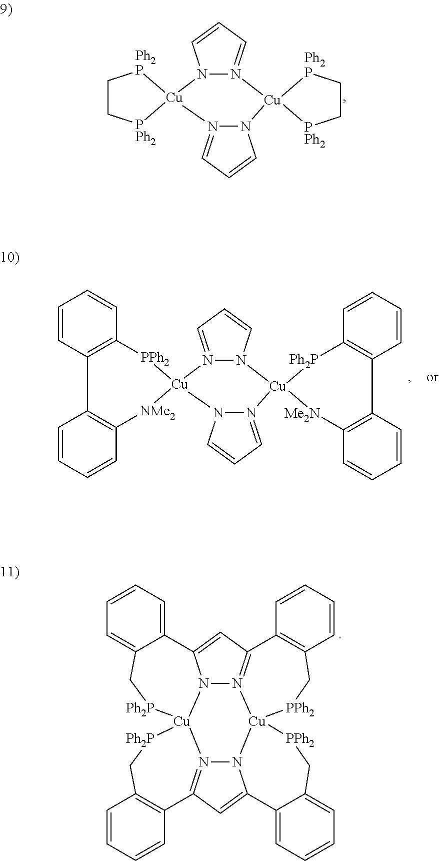

In one embodiment, the compound of Structure 1 has a molecular weight from 950 to 10,000 g/mole, further from 950 to 8,000 g/mole, further from 950 to 5,000 g/mole.

In one embodiment, the compound of Structure 1 has a S₁-T₁ Gap from 0.001 eV to 0.50 eV, further from 0.001 eV to 0.45 eV, further from 0.001 eV to 0.40 eV, further from 0.001 eV to 0.35 eV, further from 0.001 eV to 0.30 eV.

In one embodiment, the compound of Structure 1 has a S₁-T₁ Gap from 0.001 eV to 0.50 eV, further from 0.005 eV to 0.45 eV, further from 0.01 eV to 0.40 eV, further from 0.02 to 0.35 eV, further from 0.05 eV to 0.30 eV.

In one embodiment, the compound of Structure 1 has a HOMO level from −4.65 eV to −4.00 eV, further from −4.60 eV to −4.05 eV, further from −4.57 eV to −4.10 eV.

In one embodiment, the compound of Structure 1 has a LUMO level from −0.45 eV to −1.10 eV, further from −0.50 eV to −1.05 eV, further from −0.55 eV to −1.00 eV.

In one embodiment, the compound of Structure 1 has a Triplet (T₁) level from 1.70 eV to 3.20 eV, further from 2.00 eV to 3.00 eV, further from 2.20 eV to 2.80 eV.

In one embodiment, the inventive composition further comprises a host material. The host material is defined as one or more compounds, or one or more polymers, that can be doped with the emitter molecules (copper complexes) invented herein. Preferred host materials include, but are not limited to, those with a triplet energy higher than that of the doped emitter molecule. One preferred host is 4,4′-N,N′-dicarbazole-biphenyl (CBP). Additional host materials can be found in Yook et al. “Organic Materials for Deep Blue Phosphorescent Organic Light-Emitting Diodes” Adv. Mater. 2012, 24, 3169-3190, and in Mi et al. “Molecular Hosts for Triplet Emitters in Organic Light-Emitting Diodes and the Corresponding Working Principle” Sci. China Chem. 2010, 53, 1679.

In one embodiment, the composition comprises greater than, or equal to, 99.00 wt %, further greater than, or equal to, 99.50 wt %, further greater than, or equal to, 99.80 wt %, further greater than, or equal to, 99.90 wt %, of the compound of Structure 1, based on the weight of the composition.

In one embodiment, the composition comprises greater than, or equal to, 99.97 wt %, further greater than, or equal to, 99.98 wt %, further greater than, or equal to, 99.99 wt %, of the compound of Structure 1, based on the weight of the composition.

The compound of Structure 1 may comprise a combination of two or more embodiments as described herein.

An inventive composition may comprise a combination of two or more embodiments as described herein.

The invention also provides a film comprising at least one layer formed from an inventive composition, including an inventive composition of one or more embodiments described herein. In a further embodiment, the film is an electroemissive film.

In one embodiment, the inventive film is formed from casting from a solution.

In one embodiment, the inventive film is formed by deposition from an evaporation process or a sublimation process in a vacuum.

The invention also provides an electronic device comprising at least one component formed an inventive composition, including an inventive composition of one or more embodiments described herein.

The invention also provides an electronic device comprising at least one component formed from an inventive film, including an inventive film of one or more embodiments described herein.

In one embodiment, for an inventive device, the compound of Structure 1 generates visible light colors, and wherein the visible light colors are arranged in a pixelated format. In a pixilated format each subpixel emits a specific color of light.

In one embodiment, for an inventive device, the compound of Structure 1 generates visible light colors, and wherein the visible light colors are arranged in a layered format. In a layered format the layers are positioned one on top of another.

In one embodiment, for an inventive device, the compound of Structure 1 generates a color blend which approximates white light.

In one embodiment, for an inventive device, the compound of Structure 1 generates a color blend, and wherein the individual colors of the color blend can be selected using an adjustable control, to generate a variable blended color.

In one embodiment, the inventive device further comprises one or more additional hole transport layers and/or one or more electron charge transport layers.

The inventive compositions are useful for application in organic light emitting diodes (OLED) or related organic electronic devices, including organic solar cells. More specifically, the invented compositions find application in individual layers of OLEDs, including HIL (hole injection layers), HTL (hole transport layers), EML (emissive layers, including host and dopant), and ETL (electron transport layers).

An inventive film may comprise a combination of two or more embodiments as described herein.

An inventive device may comprise a combination of two or more embodiments as described herein.

### DEFINITIONS

The term “hydrocarbon,” as used herein, refers to a chemical group containing only hydrogen and carbon atoms.

The term “substituted hydrocarbon,” as used herein, refers to a hydrocarbon in which at least one hydrogen atom is substituted with a substituent comprising at least one heteroatom. Heteroatoms include, but are not limited to, O, N, P and S. Substituents include, but are not limited to, halide, OR′, NR′₂, PR′₂, P(═O)R′₂, SiR′₃; where each R′ is a C₁-C₂₀ hydrocarbyl group.

The term “hydrocarbylene,” as used herein, refers to a divalent (diradical) chemical group containing only hydrogen and carbon atoms.

The term “substituted hydrocarbylene,” as used herein, refers to a hydrocarbylene, in which at least one hydrogen atom is substituted with a substituent that comprises at least one heteroatom. Heteroatoms include, but are not limited to, O, N, P and S. Substituents include, but are not limited to, halide, OR′, NR′₂, PR′₂, P(═O )R′₂, SiR′₃; where each R′ is a C₁-C₂₀ hydrocarbyl group.

The term “heterohydrocarbylene,” as used herein, refers to a hydrocarbylene, in which at least one carbon atom, or CH group, or CH2 group, is substituted with a heteroatom or a chemical group containing at least one heteroatom. Heteroatoms include, but are not limited to, O, N, P and S.

The term “substituted heterohydrocarbylene,” as used herein, refers to a heterohydrocarbylene, in which at least one hydrogen atom is substituted with a substituent that comprises at least one heteroatom. Heteroatoms include, but are not limited to, O, N, P and S. Substituents include, but are not limited to, halide, OR′, NR′₂, PR′₂, P(═O)R′₂, SiR′₃; where each R′ is a C₁-C₂₀ hydrocarbyl group.

The term “alkyl,” as described herein, refers to an organic radical derived from an aliphatic hydrocarbon by deleting one hydrogen atom therefrom. An alkyl group may be a linear, branched, cyclic or a combination thereof.

The term “substituted alkyl,” as used herein, refers to an alkyl in which at least one hydrogen atom is substituted with a substituent that comprises at least one heteroatom. Heteroatoms include, but are not limited to, O, N, P and S. Substituents include, but are not limited to, halide, OR′, NR′₂, PR′₂, P(═O)R′₂, SiR′₃; where each R′ is a C₃₀-C₁₀₀ hydrocarbyl group.

The term “heteroalkyl,” as described herein, refers to an alkyl group, in which at least one carbon atom or CH group or CH₂ is substituted with a heteroatom or a chemical group containing at least one heteroatom. Heteroatoms include, but are not limited to, O, N, P and S.

The term “substituted heteroalkyl,” as used herein, refers to a heteroalkyl in which at least one hydrogen atom is substituted with a substituent comprising at least one heteroatom. Heteroatoms include, but are not limited to, O, N, P and S. Substituents include, but are not limited to, halide, OR′, NR′₂, PR′₂, P(═O)R′₂, SiR′₃; where each R′ is a C₁-C₂₀hydrocarbyl group.

The term “aryl,” as described herein, refers to an organic radical derived from aromatic hydrocarbon by deleting one hydrogen atom therefrom. An aryl group may be a monocyclic and/or fused ring system, each ring of which suitably contains from 5 to 7, preferably from 5 or 6 atoms. Structures wherein two or more aryl groups are combined through single bond(s) are also included. Specific examples include, but are not limited to, phenyl, naphthyl, biphenyl, anthryl, indenyl, fluorenyl, benzofluorenyl, phenanthryl, triphenylenyl, pyrenyl, perylenyl, chrysenyl, naphtacenyl, fluoranthenyl and the like. The naphthyl may be 1-naphthyl or 2-naphthyl, the anthryl may be 1-anthryl, 2-anthryl or 9-anthryl, and the fluorenyl may be any one of 1-fluorenyl, 2-fluorenyl, 3-fluorenyl, 4-fluorenyl and 9-fluorenyl.

The term “substituted aryl,” as used herein, refers to an aryl, in which at least one hydrogen atom is substituted with a substituent comprising at least one heteroatom. Heteroatoms include, but are not limited to, O, N, P and S. Substituents include, but are not limited to, halide OR′, NR′₂, PR′₂, P(═O)R′₂, SiR′₃; where each R′ is a C₃₀-C₁₀₀ hydrocarbyl group.

The term “heteroaryl,” as described herein, refers to an aryl group, in which at least one carbon atom or CH group or CH₂ is substituted with a heteroatom or a chemical group containing at least one heteroatom. Heteroatoms include, but are not limited to, O, N, P and S. The heteroaryl may be a 5- or 6-membered monocyclic heteroaryl or a polycyclic heteroaryl which is fused with one or more benzene ring(s), and may be partially saturated. The structures having one or more heteroaryl group(s) bonded through a single bond are also included. The heteroaryl groups may include divalent aryl groups of which the heteroatoms are oxidized or quarternized to form N-oxides, quaternary salts, or the like. Specific examples include, but are not limited to, monocyclic heteroaryl groups, such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl; polycyclic heteroaryl groups, such as benzofuranyl, fluoreno[4,3-b]benzofuranyl, benzothiophenyl, fluoreno[4,3-b]benzothiophenyl, isobenzofuranyl, benzimidazolyl, benzothiazolyl, benzisothiazolyl, benzisoxazolyl, benzoxazolyl, isoindolyl, indolyl, indazolyl, benzothia-diazolyl, quinolyl, isoquinolyl, cinnolinyl, quinazolinyl, quinoxalinyl, carbazolyl, phenanthridinyl and benzodioxolyl; and corresponding N-oxides (for example, pyridyl N-oxide, quinolyl N-oxide) and quaternary salts thereof.

The term “substituted heteroaryl,” as used herein, refers to a heteroaryl in which at least one hydrogen atom is substituted with a substituent comprising at least one heteroatom.

Heteroatoms include, but are not limited to, O, N, P and S. Substituents include, but are not limited to, halide OR′, NR′₂, PR′₂, P(═O)R′₂, SiR′₃; where each R′ is a C₁-C₂₀ hydrocarbyl group.

The term “fluorescent emission,” as used herein, refers to radiative emission from a singlet excited state.

The term “phosphorescent emission,” as used herein, refers to radiative emission from a triplet excited state. For emitters that undergo primarily fluorescent emission, the term “triplet harvesting,” as used herein, refers to the ability to also harvest triplet excitons.

The term “thermally activated delayed fluorescence (TADF),” as used herein, refers to fluorescent emission utilizing triplet harvesting, enabled by a thermally accessible singlet excited state.

### EXPERIMENTAL

Reagents and Test Methods

All solvents and reagents were obtained in the highest available purity from commercial vendors, including Sigma-Aldrich, TCI, Strem and Alfa Aesar. Mesitylcopper(I) was prepared by adapting a known literature method ([1]: Eriksson, H.; Håkansson, M. Organometallics, 1997, 16, 4243); although characterized as a tetramer and pentamer in the solid state, for ease of calculating stoichiometry; mesitylcopper(I) was treated as a monomer (MW=182.7 Da) in the experimental procedures. Dry solvents were obtained from an in-house purification/dispensing system (hexane, toluene, tetrahydrofuran and diethyl ether), or purchased from Sigma-Aldrich, and stored over activated 3 Åmolecular sieves. All experiments involving water sensitive or air sensitive compounds were conducted in a nitrogen-purged glovebox.

¹H-NMR-spectra (500 MHz or 400 MHz) were obtained on a Varian VNMRS-500 or VNMRS-400 spectrometer at 25° C., unless otherwise noted. The chemical shifts were referenced as follows: CHCl₃ (δ=7.26) in CDCl₃, Benzene-d₅ (δ7.16) in Benzene-d₆, or CHDCl₂ in CD₂Cl₂ (δ5.32).

³¹P NMR spectra were obtained on a Varian VNMRS-500 or VNMRS-400 spectrometer at 25° C., and referenced externally to H₃PO₄ (δ0.00).

The ground-state (S₀) and first excited triplet-state (T₁) configurations of the copper complexes were computed using Density Functional Theory (DFT) at B3LYP/6-31 glevel. The energies of highest occupied molecular orbital (HOMO) and lowest unoccupied molecular orbital (LUMO) were obtained from the S₀ configuration. The energy of the T₁ state was computed as the difference in energy between the minima of S₀ and T₁ potential energy surfaces (PES). The S₁-T₁ gap was computed as the vertical energy between the S₁ and T₁ states, at the T₁ configuration. The S₁-T₁ gap was computed using Time Dependent Density Functional Theory (TDDFT). All the calculations were performed using G09 suit of programs [2].

Frisch, M. J. T., G. W.; Schlegel, H. B.; Scuseria, G. E.; Robb, M. A.; Cheeseman, J. R.; Montgomery, Jr., J. A.; Vreven, T.; Kudin, K. N.; Burant, J. C.; Millam, J. M.; Iyengar, S. S.; Tomasi, J.; Barone, V.; Mennucci, B.; Cossi, M.; Scalmani, G.; Rega, N.; Petersson, G. A.; Nakatsuji, H.; Hada, M.; Ehara, M.; Toyota, K.; Fukuda, R.; Hasegawa, J.; Ishida, M.; Nakajima, T.; Honda, Y.; Kitao, O.; Nakai, H.; Klene, M.; Li, X.; Knox, J. E.; Hratchian, H. P.; Cross, J. B.; Bakken, V.; Adamo, C.; Jaramillo, J.; Gomperts, R.; Stratmann, R. E.; Yazyev, O.; Austin, A. J.; Cammi, R.; Pomelli, C.; Ochterski, J. W.; Ayala, P. Y.; Morokuma, K.; Voth, G. A.; Salvador, P.; Dannenberg, J. J.; Zakrzewski, V. G.; Dapprich, S.; Daniels, A. D.; Strain, M. C.; Farkas, O.; Malick, D. K.; Rabuck, A. D.; Raghavachari, K.; Foresman, J. B.; Ortiz, J. V.; Cui, Q.; Baboul, A. G.; Clifford, S.; Cioslowski, J.; Stefanov, B. B.; Liu, G.; Liashenko, A.; Piskorz, P.; Komaromi, I.; Martin, R. L.; Fox, D. J.; Keith, T.; Al-Laham, M. A.; Peng, C. Y.; Nanayakkara, A.; Challacombe, M.; Gill, P. M. W.; Johnson, B.; Chen, W.; Wong, M. W.; Gonzalez, C.; and Pople, J. A; A.02 ed.; Gaussian Inc.: Wallingford Conn., 2009.

### Inventive Examples

### Synthesis of 1,2-bis(diphenylphosphino)benzene copper(I) pyrazolate dimer (Copper Complex 1)

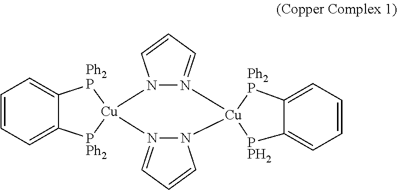

In a glovebox, a jar was charged with 1,2-bis(diphenylphsphino)benzene (5.13 g, 11.5 mmol) and toluene (25 mL). Mesitylcopper(I) (2.31 g, 12.6 mmol), dissolved in toluene (25 mL), was filtered through a 45 micron syringe filter, into the jar, and the mixture was heated to 60° C., and pyrazole (0.783 g, 11.5 mmol) was added. The mixture was sealed, and stirred for 17 hours. A substantial amount of solid had formed, and the mixture was heated to reflux, to dissolve the solid. After slowly cooling the mixture, over several hours, to room temperature, the mixture was left undisturbed for several hours. The resulting crystals were isolated, and washed with hexanes (2×20 mL), to afford approximately 5.4 g of crystals. These crystals were triturated with a mixture of hexanes (30 mL) and toluene (60 mL). After filtration and washing with hexanes (20 mL), the title complex was isolated as a yellow solid (3.73 g). Additional material was isolated from the various washings, but was not used for sublimation. A portion of the isolated crystals (3 g) were sublimed under high vacuum (4.6×10⁻⁵ mbar) at 265° C., and 2.75 g of the compound was recovered in the collection zone. Analysis by 1H NMR spectroscopy indicated only the presence of title compound.

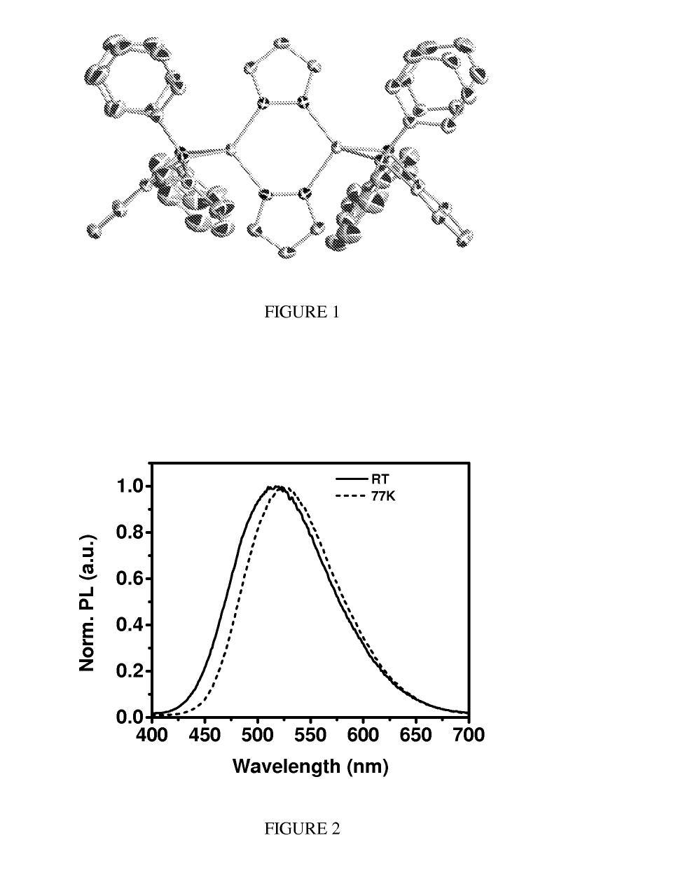

Single crystal X-Ray diffraction studies were performed on crystals grown from C₆D₆ in an NMR tube. ¹H NMR (400 MHz, C₆D₆): δ7.58 (d, J=1.8 Hz, 4H), 7.48 (dtd, J=5.6, 4.4, 3.2 Hz, 4H), 7.25 (m, 16H), 6.97-6.82 (m, 28H), 6.44 (t, J=1.8 Hz, 2H) ppm. ¹³C NMR (151 MHz, C₆D₆): δ144.35 (t, J=29.6 Hz), 104.06, 135.74 (t, J=12.3 Hz), 134.47, 134.17 (t, J=8.5 Hz), 129.61, 128.76, 102.42 ppm. ³¹P NMR (162 MHz, C₆D₆): δ-17.4 ppm. FIG. 1 depicts a solid state structure of Copper Complex 1. FIG. 2 depicts the emission spectrum for Copper Complex 1 in a PMMA film at room temperature (RT) and 77K.

### Synthesis of 1,2-bis(diphenylphosphino)benzene copper(I) 4-trifluoromethylpyrazolate dimer (Copper Complex 2)

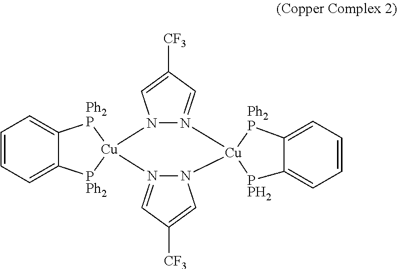

In a glovebox, a vial was charged with 1,2-bis(diphenylphosphino)benzene (0.200 g, 0.45 mmol) and 4-trifluoromethylpyrazole (0.061 g, 0.45 mmol). Toluene (5 mL) was added, followed by a mesitylcopper(I) solution (0.068 g, 0.3733 mmol, in 5 mL toluene). The resulting yellow solution was heated at 60° C. for 15 hours. The mixture was cooled, and concentrated, and washed with hexanes (3×10 mL), to provide a material that was primarily the desired product. The mixture was further washed with toluene (2×2 mL), and dried to afford the title complex, as a yellow solid (144 mg). Pale yellow crystals were grown out of a concentrated toluene solution. Single crystal X-Ray diffraction studies supported the ChemDraw structure shown above. ¹H NMR(400 MHz, CD₂Cl₂): δ7.47 (m 8H), 7.23 (m, 8H), 7.10 (m, 16H), 6.98 (m, 20H) ppm. ¹⁹F NMR (376 MHz, CD₂Cl₂): δ-54.56 ppm. ³¹P NMR (162 MHz, CD₂Cl₂) δ-12.67 ppm.

### Synthesis of (Oxybis(2,1-phenylene))bis(diphenylphosphine)copper(I) pyrazolate dimer (Copper Complex 3)

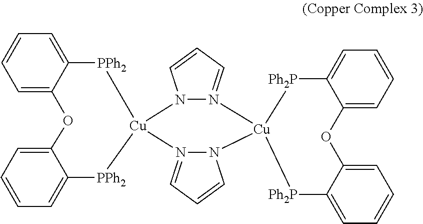

In a nitrogen-purged glove box, oxybis(2,1-phenylene))bis(diphenylphosphine (3.0 g, 5.57 mmol) was dissolved in 30 mL toluene, along with pyrazole (0.38 g, 5.52 mmol). While the mixture was stirring, a 10 mL solution of mesitylcopper(I) (1.0 g, 5.47 mmol) was added. The resulting solution was placed in an aluminum heating block, and stirred with a PTFE-coated stir bar. Solid formed quickly. The mixture was heated at a 70° C. block temperature for two hours. After cooling to room temperature, the solid was isolated by filtration, and dried in vacuo. The resulting solid was not soluble in CH₂Cl₂, toluene at 110° C., or ethyl acetate. However, 50 mg of solid was suspended in 1.68 mL of 25 wt % poly(methylmeth-acrylate) (PMMA) in CH₂Cl₂, stirred overnight, and filtered. Solvent was removed in vacuo, to yield a copper doped PMMA. The PMMA sample was dissolved in CD₂Cl₂, and characterized by ¹H and ³¹P NMR spectroscopy. The bulk powder was purified further by sublimation. The sublimed material was characterized in PMMA/CH₂Cl₂ (after filtration) by NMR spectroscopy; the spectrum matched that of the unsublimed material. ³¹P NMR (162 MHz, CD₂Cl₂) δ-19.2 ppm.

### Synthesis of (Oxybis(2,1-phenylene))bis(diphenylphosphine)copper(I) triazolate dimer (Copper Complex 4)

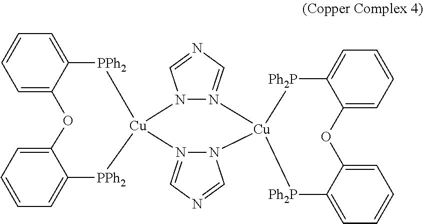

In a nitrogen-purged glove box, (oxybis(2,1-phenylene))bis(diphenylphosphine, (0.90 g, 1.67 mmol) was dissolved in 10 mL toluene, and combined with mesitylcopper(I) (0.30 g, 1.64 mmol), dissolved in 5 mL toluene. After stirring at room temperature for about 5 minutes, a suspension of 1,2,4-triazole (0.115 g, 1.66 mmol), in toluene (5 mL), was added. The resulting mixture was heated at approximately 100° C. for 2 hours, and then cooled, and stirred overnight at 60° C. The off-white solid was filtered using a 20 micron polyethylene frit. The solid was rinsed with toluene and hexanes, and dried under vacuum. A sample of the product (150 mg) was suspended in 3.0 mL of a 25 wt % PMMA solution in CH₂Cl₂. The white solid was very poorly soluble, so the mixture was stirred overnight. A significant amount of white solid remained. The mixture was filtered through a 0.45 micron PTFE syringe frit. Solvent was removed from the resulting viscous solution by air drying, followed by heating to 70° C. under vacuum. The resulting doped PMMA solid was dissolved in deuterated methylene chloride and analyzed by ¹H and ³¹P NMR spectroscopy. ³¹P NMR (162 MHz, CD₂Cl₂) δ-17.0 ppm.

### Synthesis of (Oxybis(2,1-phenylene))bis(diphenylphosphine)copper(I) (4-trifluoro-methylpyrazolate) dimer (Copper Complex 5)

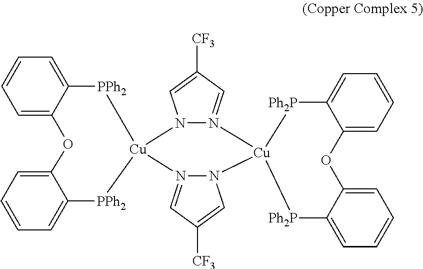

In a nitrogen-purged glove box, a vial, equipped with a TEFLON coated magnetic stir bar, was charged with (oxybis(2,1-phenylene))bis(diphenylphosphine) (1.00 g, 1.86 mmol) and 4-trifluoromethylpyrazole (0.253 g, 1.86 mmol). Toluene (5 mL) was added, followed by mesitylcopper(I) (0.283 g, 1.55 mmol) dissolved in toluene (5 mL). The resulting yellow solution was stirred at approximately 60° C. for 15 hours. The mixture was cooled and filtered. The white solid was washed with toluene (5 mL) and hexanes (5 mL), and dried to afford the title compound as a white solid (0.785 g). ³¹P and ¹⁹F NMR spectra were taken in 25 wt % PMMA in dichloromethane. ¹⁹F NMR (376 MHz, CD₂Cl₂): δ-56.63. ³¹P NMR (162 MHz, CD₂Cl₂) δ-19.73 ppm.

### Synthesis of (Oxybis(2,1-phenylene))bis(diphenylphosphine)copper(I) 4-(4-pyridyl)-pyrazolate dimer (Copper Complex 6)

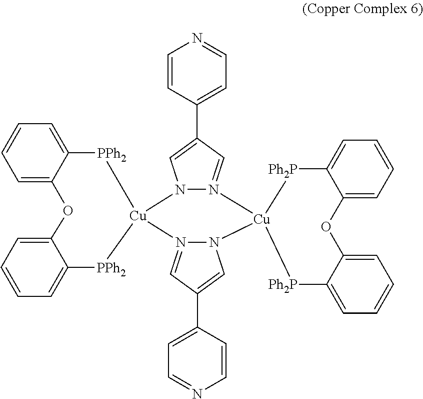

In a nitrogen-purged glove box, (oxybis(2,1-phenylene))bis(diphenylphosphine) (0.90 g, 1.67 mmol) was dissolved in 10 mL toluene. A solution of mesitylcopper(I) (0.30 g, 1.64 mmol), dissolved in toluene(5 mL), was added. After a few minutes, 4-(1H-pyrazole-4-yl)pyridine (0.24 g, 1.65 mmol) was added, and the resulting mixture was stirred at about 80° C. for 3 hours. The mixture was cooled to room temperature, and the solid formed was collected by filtration, and rinsed with toluene and hexanes, to afford the title compound (1.02 g), after drying under vacuum. Single crystals were grown from CD₂Cl₂, and characterized by X-Ray crystallography, supporting the above molecular structure. ³¹P NMR (162 MHz, CD₂Cl₂) δ-18.2 ppm.

### Syntheses of (Oxybis(2,1-phenylene))bis(diphenylphosphine)copper(I) (3-methyl-4-phenyl)pyrazolate dimer (Copper Complex 7)

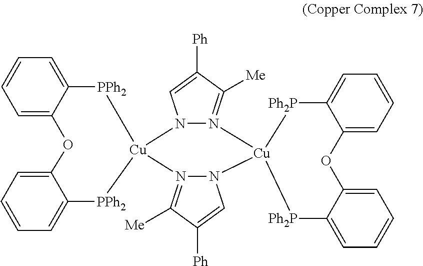

In a nitrogen-purged glove box, (oxybis(2,1-phenylene))bis(diphenylphosphine) (1.0 g, 1.85 mmol) and toluene (30 mL) were added to a glass jar, equipped with a PTFE-coated stir bar. While stirring, mesitylcopper(I) (0.31 g, 1.70 mmol) was added. After a few minutes, 3-methyl-4-phenyl-1H-pyrazole (0.30 g, 1.90) was added, and the resulting mixture was heated at 90° C. for 3 hours. The mixture was then cooled to 60° C., and stirred overnight.

After cooling to room temperature, the solid that had formed was collected by filtration. The isolated solid was rinsed with toluene, followed by hexanes, and dried at 70° C., under vacuum, to afford the title compound (0.66 g). Crystals were grown by slow evaporation of dichloromethane, and characterized by single crystal X-Ray crystallography, supporting the above molecular structure. ³¹P NMR (162 MHz, CD₂Cl₂) δ-16.7 ppm.

### Synthesis of 4,5-Bis(diphenylphosphino)-9,9-dimethylxanthene Copper(I) 4-(4-pyridyl)pyrazolate dimer (Copper Complex 8)

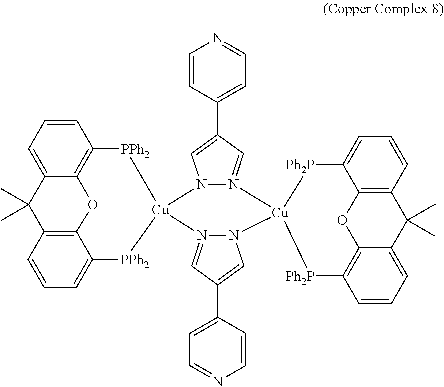

In a nitrogen-purged glove box, XantPhos (4,5-bis(diphenylphosphino)-9,9-dimethylxanthene, 0.90 g, 1.56 mmol) and toluene (15 mL) were added to a jar, equipped with a magnetic stir bar. A solution of mesitylcopper(I) (0.28 g), dissolved in toluene (10 mL), was then added. After stirring the resulting solution, at room temperature, for about 5 minutes, 4-(1H-pyrazole-4-yl)pyridine (0.23 g, 1.58 mmol) was added, and the resulting mixture was heated to 80° C., and the reaction mixture was stirred for 3 hours. The reaction mixture was cooled to room temperature, and the solid was collected by filtration, and rinsed with toluene (10 mL) and hexanes (10 mL), to afford a white solid upon drying (1.09 g). ³¹P NMR (202 MHz, CD₂Cl₂) δ-16.4 ppm.

### Synthesis of 1,2-Bis(diphenylphosphino)ethane copper(I) pyrazolate (Copper Complex 9)

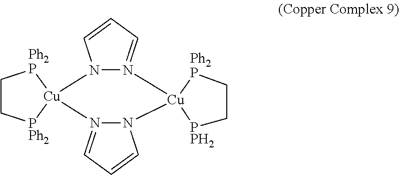

In a nitrogen-purged glove box, 1,2-bis(diphenylphosphino)ethane (1.1 g, 2.76 mmol) was combined with pyrazole (0.19 g, 2.79 mmol) in a glass jar, equipped with a PTFE-coated stir bar, followed by the addition of toluene (30 mL). Stirring was initiated, and a solution of mesitylcopper(I) (0.49 g, 2.68 mmol), in toluene (about 5 mL), was then added. The jar was capped, and the resulting solution was stirred at 100° C. for 2 hours. The mixture was then cooled to room temperature. Hexanes (˜30 mL) were added, and all volatiles were removed in vacuo. The residue was suspended in hexanes (20 mL), and the solid was collected by filtration. The solid was dried under vacuum, to afford an off white solid (0.86 g). The solid was characterized by ¹H and ³¹P NMR spectroscopy in CD₂Cl₂. The spectra were consistent with the chemical structure shown above, along with mesitylene (0.3 molar equivalents relative to desired product). ³¹P NMR (202 MHz, CD₂Cl₂) δ-13.3 ppm.

### Synthesis of 2-Diphenylphosphino-2′-(N,N-dimethylamino)biphenyl copper(I) pyrazolate dimer (Copper Complex 10)

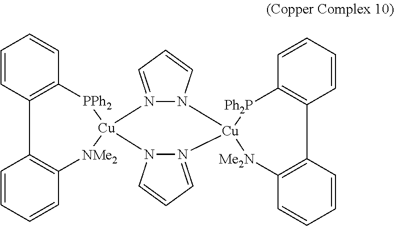

In a nitrogen-purged glove box, a jar equipped with a stir bar was charged with 2-diphenylphosphino-2′-(N,N-dimethylamino)biphenyl (PhDavePhos, 0.75 g, 1.96 mmol) and toluene (20 mL). Mesitylcopper(I) (0.35 g, 1.92 mmol), dissolved in toluene (10 mL), was then added. After stirring at room temperature for about 5 minutes, pyrazole (0.14 g, 2.05 mmol) was added as a solid. The resulting mixture was at 100° C., for 2 hours, with stirring. The solvent was mostly removed in vacuo, and the resulting mixture, in about 2 mL toluene, was precipitated with 40 mL hexanes. The solid was collected by filtration, and rinsed with hexanes. The white solid was dried under vacuum to yield the title complex (0.42 g), as an off white solid.

### Comparative Examples

### Synthesis of triphenylphosphinecopper(I) pyrazolate dimer (Copper Complex A)

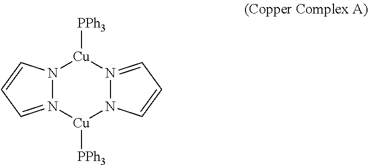

In a nitrogen-purged glove box, triphenylphosphine (1.5 g, 5.7 mmol) and toluene (20 mL) were added to a jar, equipped with a TEFLON coated magnetic stir bar. A solution of mesitylcopper(I) (0.51 g, 2.8 mmol), in toluene (10 mL), was then added, while stirring. After stirring at room temperature for about 5 minutes, solid pyrazole (0.20 g, 2.8 mmol) was added. The resulting mixture was heated to 80° C., and stirred for 2 hours. The white solid that had formed, was collected by filtration, and dried under vacuum, to yield a white powder (0.91 g). ¹H and ³¹P NMR spectroscopic analysis was consistent with the presence of only one PPh₃ per copper atom in the material isolated. ³¹P NMR (202 MHz, CD₂Cl₂) δ-1.7 ppm. The formation of a three coordinate, copper complex supports the necessity of bidentate ligands to render the complex four coordinate.

The solid (45 mg) was dissolved in 3.0 mL of a 25 wt % solution of PMMA in methylene chloride. After stirring for 20 minutes, the solution was filtered. A film was made by drop casting the solution on PTFE, and heating the material to 60° C. After setting the film open to ambient air overnight, the film turned a dark blue color, suggesting that the three coordinate analogues of the above dimers were air sensitive, an undesirable property for emitter molecules.

### Synthesis of (Oxybis(2,1-phenylene))bis(diphenylphosphine)copper(I) (4-cyano-pyazolate) dimer (Copper Complex B)

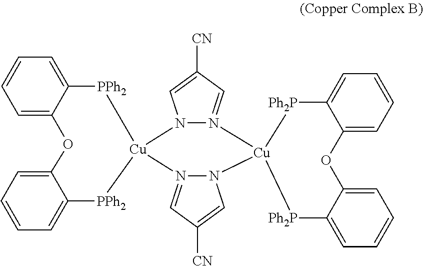

In a nitrogen-purged glove box, (oxybis(2,1-phenylene))bis(diphenylphosphine) (1.0 g, 1.86 mmol) and toluene (20 mL) were added to a glass jar, containing a TEFLON coated stir bar. A solution of mesitylcopper(I) (0.34 g, 1.86 mmol), in toluene (10 mL), was then added, while stirring. After a few minutes, 4-cyanopyrazole (0.17 g, 1.81 mmol) was added, the jar was capped, and the resulting mixture was stirred at 60° C. for 3 hours. After cooling to room temperature, the milky white mixture was concentrated, and further dried under vacuum for one hour at 110° C. The resulting white solid (0.78 g) was isolated. A PMMA film of this complex did not show emission upon UV-excitation.

Photochemical Characterization of Copper Complexes

Emitter-doped polymer films utilized for photoluminescence spectroscopy were prepared by dissolving poly(methyl methacrylate) (PMMA) and the respective copper complex (targeting about 10 wt % emitter relative to the PMMA) in either THF or CH₂Cl₂. In certain cases, only partial dissolution of the copper complex was observed. The PMMA/copper complex mixtures were filtered through 45 μm PTFE filters, and drop cast onto glass microscope coverslips. The resulting films were dried for 15 hours, at ambient temperature and pressure, under a nitrogen atmosphere. They were then dried at 60° C., in a vacuum oven, at approximately 1×10⁻² torr, for several hours.

Photoluminescence quantum efficiency measurements were conducted on the polymer films (prepared as described above) using an integrating sphere coupled to a fluorimeter. The method is an adaptation of well-known procedures, and accepted in open literature ([3]: De Mello, J. C.; Wittman, H. F.; Friend, R. H. Adv. Mater. 1997, 9, 230). For reference, data were collected using an excitation wavelength of 355 nm (approximately 4 nm fwhm), at room temperature, in air. The wavelength range utilized for the excitation integral was 345-365 nm. The wavelength range utilized for the emission integral varied, depending on the position and width of the emission profile of individual emitters. As an example, the wavelength range utilized for [Cu(DPPB)(μ-pz)]2 was 440-700 nm.

Room temperature and 77K spectra, reported herein, are steady-state emission profiles collected on polymer films inside the sample chamber of the fluorimeter. The profiles were collected using an excitation wavelength of 355 nm. The films were studied under a nitrogen atmosphere, in borosilicate NMR tubes that were placed into quartz tipped EPR dewars. Both, room temperature and low temperature spectra were acquired in this manner. Low temperature spectra were acquired upon filling the dewar with liquid nitrogen. All results are shown in Tables 1 and 2. Additional energy levels are shown in Table 3.

TABLE 1
Summary of Room Temperature Emission
Quantum Yields in Polymer Film.

| | | Emission | |
|---|---|---|---|
| Emitter Example | | Maximum | ΦPL (%) |
| [Cu(DPPB)(μ-pz)]2 | Copper Complex 1 | 517 nm | 47-75 |
| [Cu(DPPB)(μ-4-CF3pz)]2 | Copper Complex 2 | 526 nm | 61.6 |
| [Cu(POP)(μ-pz)]2 | Copper Complex 3 | 465 nm | 24-48 |
| [Cu(POP)(μ-trz)]2 | Copper Complex 4 | 460 nm | 32-43 |
| [Cu(POP)(μ-4CF3pz)]2 | Copper Complex 5 | 460 nm | 48 |
| [Cu(POP)(μ-4pypz)]2 | Copper Complex 6 | 485 nm | 24 |
| [Cu(POP)(μ-3Me,4Phpz)]2 | Copper Complex 7 | 470 nm | 54 |
| [Cu(Xantphos)(μ-4pypz)]2 | Copper Complex 8 | 495 nm | 33 |
| [Cu(dppe)(μ-pz)]2 | Copper Complex 9 | 515 nm | <3 |
| [Cu(PhDavePhos)(μ-pz)]2 | Copper Complex 10 | 512 nm | 7 |
| [Cu(PPh3)(μ-pz)]2 | Copper Complex A | 467 nm | 4.5 |
| [Cu(POP)(μ-4-CNpz)]2 | Copper Complex B | Not | NA* |
| | | detected | |

*NA = Not available

TABLE 2
Room Temp vs. 77K Photoluminescence
Comparison for Select Emitters

| | | RT | 77K |
|---|---|---|---|
| | | Emission | Emission |
| Emitter Example | | Maximum | Maximum |
| [Cu(DPPB)(μ-pz)]2 | Copper Complex 1 | 517 nm | 525 nm |
| [Cu(DPPB)(μ-4-CF3pz)]2 | Copper Complex 2 | 526 nm | 538 nm |
| [Cu(POP)(μ-pz)]2 | Copper Complex 3 | 465 nm | 475 nm |
| [Cu(POP)(μ-trz)]2 | Copper Complex 4 | 460 nm | 464 nm |
| [Cu(POP)(μ-4CF3pz)]2 | Copper Complex 5 | 460 nm | 462 nm |
| [Cu(Xantphos)(μ-4pypz)]2 | Copper Complex 8 | 495 nm | 497 nm |
| [Cu(PhDavePhos)(μ-pz)]2 | Copper Complex 10 | 512 nm | 512 nm |
| [Cu(PPh3)(μ-pz)]2 | Copper Complex A | 467 nm | 481 nm |

TABLE 3
Frontier Orbital Energies (eV), T₁ Energies (eV) and
S₁-T₁ Gap (eV) for Selected Emitters

| | HOMO | LUMO | T₁ | |
|---|---|---|---|---|
| | (eV) | (eV) | (eV) | S₁-T₁ Gap (eV) |
| Copper Complex 1 | −4.23 | −0.80 | 2.25 | 0.08 |
| Copper Complex 2 | −4.55 | −0.99 | 2.33 | 0.06 |
| Copper Complex 3 | −4.20 | −0.66 | 2.28 | 0.06 |
| Copper Complex 4 | −4.45 | −0.75 | 2.43 | 0.06 |
| Copper Complex 5 | −4.45 | −0.86 | 2.46 | 0.06 |
| Copper Complex 6 | −4.56 | −0.86 | 2.76 | 0.06 |
| Copper Complex 7 | −4.17 | −0.76 | 2.20 | 0.06 |
| Copper Complex 9 | −4.23 | −0.55 | 2.76 | 0.13 |

The inventive complexes prepared here demonstrate that a range of emission colors can be obtained upon excitation, including those with emission maxima consistent with green and blue emission colors (Table 1). The red shift of the emission maxima for these complexes demonstrates that these molecules undergo TADF emission (Table 2). The calculated “S1-T1 ” Gap for these molecules (Table 3) also indicates that a TADF-type emission mechanism is viable. Further, the calculated HOMO and LUMO values support that these complexes would be suitable in the OLED device stack shown in Table 4.

Electroluminescent Device

An electroluminescent device may be constructed using the following host, HTL and ETL compounds, as shown in Table 4, and standard anodes (ITO) and cathodes (Al).

TABLE 4
Electroluminescent Device

| | HTL | Dopant | Host | ETL |
|---|---|---|---|---|
| Material | TPD | Copper Complex 1 | CBP | AlQ3 |
| LUMO | −0.78 | −0.8 | −1.23 | −1.73 |
| HOMO-LUMO Gap | −3.89 | −3.43 | −4.08 | −3.27 |
| HOMO | −4.67 | −4.23 | −5.31 | −5 |
| Triplet | 3.1 | 2.25 | 3.27 | 2.88 |

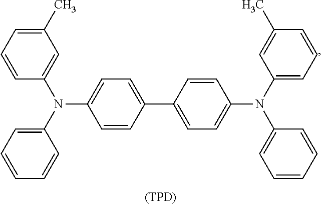 [SMILES: Cc1cccc(N(c2ccccc2)c2ccc(-c3ccc(N(c4ccccc4)c4cccc(C)c4)cc3)cc2)c1 ; "(TPD)"]

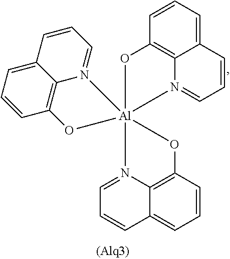

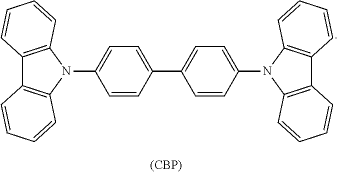 [SMILES: c1ccc2c(c1)c1ccccc1n2-c1ccc(-c2ccc(-n3c4ccccc4c4ccccc43)cc2)cc1 ; "(CBP)"]

1. A composition comprising a compound selected from Structure 1: 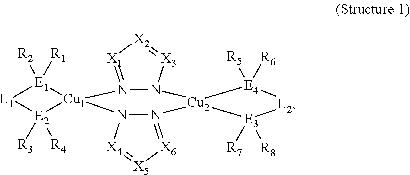
wherein E1, E2, E3 and E4 are each independently Nitrogen (N) or Phosphorus (P);
Cu1 and Cu2 are each Copper;
X1 is Nitrogen or C-R9, where C is Carbon, and R9 is selected from the following: hydrogen, a substituted or unsubstituted alkyl, a substituted or unsubstituted heteroalkyl, a substituted or unsubstituted aryl, or a substituted or unsubstituted heteroaryl;
X2 is Nitrogen or C-R10, where C is Carbon, and R10 is selected from the following: hydrogen, a substituted or unsubstituted alkyl, a substituted or unsubstituted heteroalkyl, a substituted or unsubstituted aryl, or a substituted or unsubstituted heteroaryl;
X3 is Nitrogen or C-R11, where C is Carbon, and R11 is selected from the following: hydrogen, a substituted or unsubstituted alkyl, a substituted or unsubstituted heteroalkyl, a substituted or unsubstituted aryl, or a substituted or unsubstituted heteroaryl;
X4 is Nitrogen or C-R12, where C is Carbon, and R12 is selected from the following: hydrogen, a substituted or unsubstituted alkyl, a substituted or unsubstituted heteroalkyl, a substituted or unsubstituted aryl, or a substituted or unsubstituted heteroaryl;
X5 is Nitrogen or C-R13, where C is Carbon, and R13 is selected from the following: hydrogen, a substituted or unsubstituted alkyl, a substituted or unsubstituted heteroalkyl, a substituted or unsubstituted aryl, or a substituted or unsubstituted heteroaryl;
X6 is Nitrogen or C-R14, where C is carbon, and R14 is selected from the following: hydrogen, a substituted or unsubstituted alkyl, a substituted or unsubstituted heteroalkyl, a substituted or unsubstituted aryl, or a substituted or unsubstituted heteroaryl;
R1, R2, R3, R4, R5, R6, R7, R8 are each independently selected from the following: hydrogen, a substituted or unsubstituted alkyl, a substituted or unsubstituted heteroalkyl, a substituted or unsubstituted aryl, or a substituted or unsubstituted heteroaryl; and
wherein L1 and L2 are each independently selected from the following: a substituted or unsubstituted hydrocarbylene, or a substituted or unsubstituted heterohydrocarbylene;
and wherein, optionally, two or more R groups (R1 through R14) may form one or more ring structures;
and wherein, optionally, one or more hydrogens may be substituted with deuterium.

2. The composition of claim 1, wherein E1, E2, E3 and E4 are each P.

3. The composition of claim 1, wherein R1, R2, R3, R4, R5, R6, R7 and R8 are each, independently, a substituted or unsubstituted aryl, further an unsubstituted aryl, and further each is phenyl.

4. The composition of claim 1, wherein at least two of X1, X2 and X3 are C—H; and at least two of X4, X5 and X6 are C—H.

5. The composition of claim 1, wherein X1 and X3 are each C—H; and X4 and X6 are each C—H.

6. (canceled)

7. The composition of claim 1, wherein L1 and L2 are each, independently, a substituted or unsubstituted alkylene, a substituted or unsubstituted arylene, or a substituted or unsubstituted heteroarylene.

8. The composition of claim 1, wherein L1=L2.

9. The composition of claim 1, wherein L1 and L2 are each, independently, selected from the following structures a) through e): 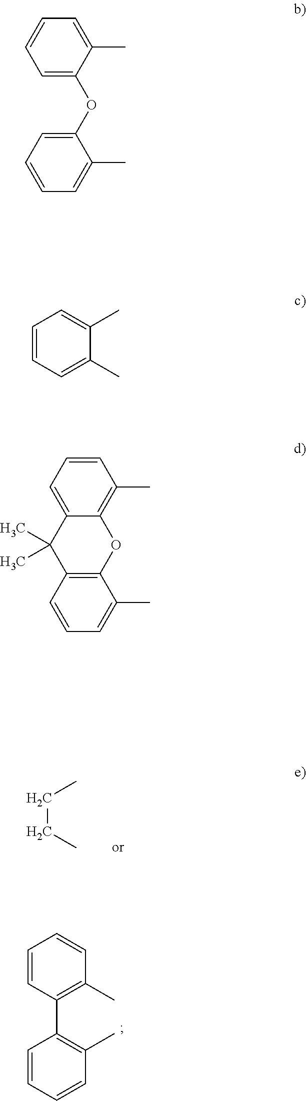
wherein, for each structure a) through e), the two “-” designations represent the respective bonds to E1 and E2, or the respective bonds to E3 and E4.

10. The composition of claim 1, wherein L1 and L2 each, independently, comprise at least one phenylene group.

11. The composition of claim 1, wherein the compound of Structure 1 is selected from the following structures 1) through 11):

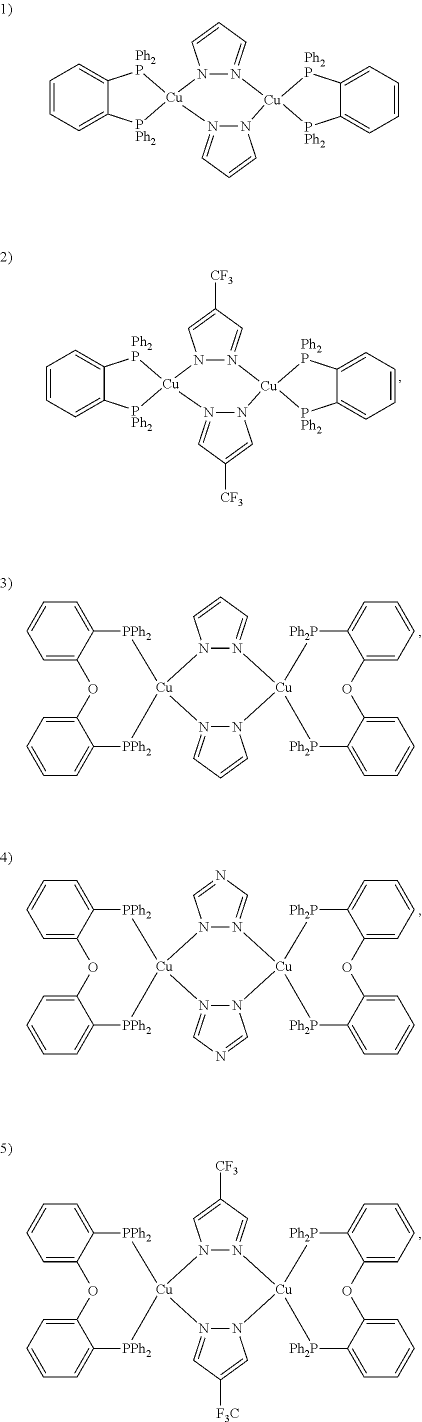

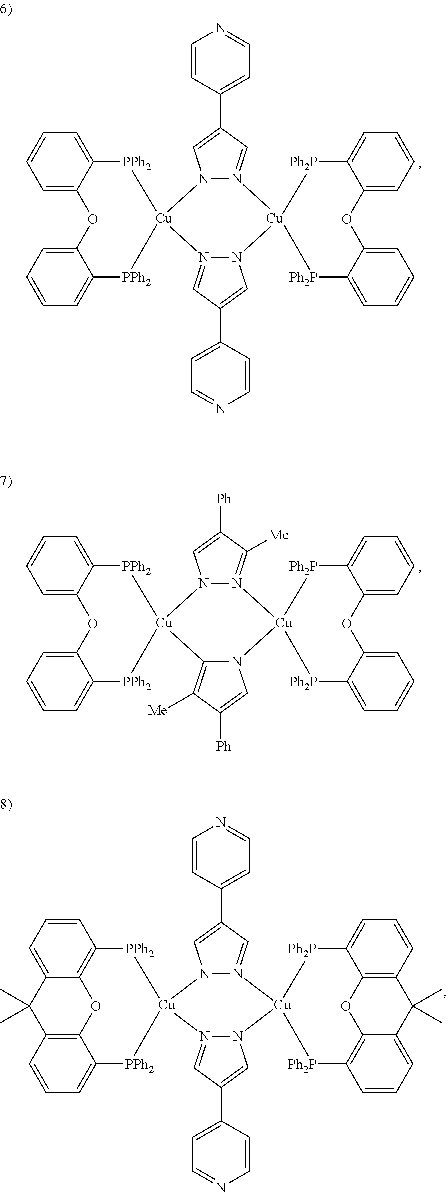

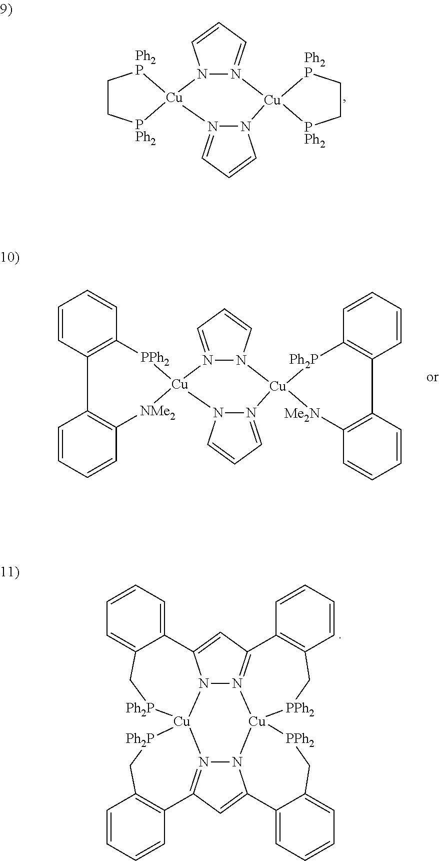

12. The composition of claim 1, wherein the compound of Structure 1 has a molecular weight from 950 to 10,000 g/mole.

13. (canceled)

14. (canceled)

15. A film formed from the composition of claim 1.

16. The film of claim 15, wherein the film is formed from casting from a solution.

17. The film of claim 15, wherein the film is formed by deposition from an evaporation process or a sublimation process in a vacuum.

18. An electronic device comprising at least one component formed the composition of claim 1.

19. An electronic device comprising at least one component formed from the film of claim 15.

20. The electronic devise of claim 18, wherein the compound of Structure 1 generates visible light colors, and wherein the visible light colors are arranged in a pixilated format.

21. The electronic devise of claim 18, wherein the compound of Structure 1 generates visible light colors, and wherein the visible light colors are arranged in a layered format.

22. The electronic devise of claim 18, wherein the compound of Structure 1 generates a color blend, which approximates white light.

23. The electronic devise of claim 18, wherein the compound of Structure 1 generates a color blend, and wherein the individual colors of the color blend can be selected using an adjustable control, to generate a variable blended color.

24. (canceled)
